(19) United States
(12) Patent Application Publication
(10) Pub. No.: US 2026/0368374 A1
(43) Pub. Date: Nov. 19, 2026

(54) SMART TRACKING AND ACCOUNTING METHOD TO REDUCE CONSTRUCITON WASTE

(71) Applicant: Marcial Yanez Carrillo, Jr., Cherry Valley, CA (US)

(72) Inventor: Marcial Yanez Carrillo, Jr., Cherry Valley, CA (US)

(21) Appl. No.: 19/209,383

(22) Filed: May 15, 2025

(51) Int. Cl. G06F 30/12; G06Q 10/087; G06Q 50/08

(52) U.S. Cl. CPC G06F 30/12; G06Q 10/087; G06Q 50/08

(57) ABSTRACT

Implementations of the disclosure relate to systems and methods for smart tracking and accounting of construction material usage to reduce construction waste. A blueprint for a construction project is obtained, which contains a set of locations, material dimensions, and material types. One or more pieces of materials for the construction project are obtained for each material type. One or more cut specifications are determined for a piece of material of the one or more materials based on the blueprint. Each portion of the piece of material is associated with a respective location of the set of locations. The one or more cut specifications, portions of the piece of material, and respective locations associated with each portion are displayed. Users are enabled, via a graphic user interface of an application, to cut the piece of material such that the piece of material is maximally utilized between the set of locations.

### TECHNICAL FIELD

Implementations of the disclosure relate to a system and method for smart tracking and accounting of construction materials to reduce construction waste.

### BACKGROUND

Construction is one of the largest industries that serves as the backbone of infrastructure development, housing, and commercial expansion. According to the United States (U.S.) Census Bureau, the U.S. alone is estimated to spend over $2,100 billion on construction (e.g., including private and public projects) each month as of February 2025. Construction refers to the process of engineering, erecting, installing, assembling, expanding, renovating, or relocating a building, structure, or other real property asset. As a result of its significant influence on development and infrastructure, the construction industry is estimated to account for approximately 13% of the global gross domestic product (GDP).

However, construction is a labor-and resource-intensive industry that can involve significant human labor, materials (e.g., wood, stones, metal, etc.) and capital to complete a project. Such a resource-intensive field produces significant waste (e.g., scraps of used materials, unused materials, etc.), with some estimates indicating that construction and demolition waste account for 30-40% of the total solid waste stream globally. Additionally, studies have indicated that up to 30% of building materials used in a construction project are wasted and put in landfills rather than used or recycled, resulting in the unnecessary consumption of raw materials (e.g., timber, stones, metal). Beyond the materials themselves, unnecessary costs are incurred for the procurement, handling, and delivery of the materials that are discarded instead of used.

Waste of resources in construction projects can be attributed to two main factors: lack of proper tracking of material usage and lack of accountability. Conventional systems fail to track materials from procurement to use at a construction site. As such, materials that are lost, misplaced, or used for the wrong purpose during a project can cause delays due to time spent searching for the lost materials and/or incur additional costs to order replacement materials. Additionally, conventional systems may consider components for a build individually and fail to determine when components can be created from the same resource to prevent waste. For example, a building project that uses wooden boards of different sizes may cut each type of board from separate wooden slabs rather than determining whether a single slab can be used to create multiple types of boards and maximize resource usage to reduce wasted construction materials.

In addition to tracking materials, conventional systems lack a way to manage the progress and efficiency of workers who are participating in the project. As such, it is difficult to determine the source of a delay or identify when workers are progressing with an efficiency that fails to satisfy an efficiency criterion (e.g., the work is progressing behind an expected project schedule). For example, it may be difficult to identify when a portion of a project (e.g., material delivery) is delayed and make accommodations (e.g., change the work assignments and/or amount of workers) based on the delay. The failure to quickly identify and address delays and/or inefficiencies can cause further delays, higher costs (e.g., from late-stage design changes, rush labor and/or overtime, etc.), and unnecessary material usage (e.g., discarded materials from changed design). Using the example above, if material delivery is delayed, then the framing of the structure may be delayed, which can delay build actions such as installing drywall or electrical wires. As such, there would be extended delays that could involve rescheduling subcontractors or workers assigned to perform each build action. In some situations, the delay may lead to design changes to accommodate for the delayed materials, which can use new materials and discard already obtained materials. Implementations of the present disclosure address the above deficiencies by providing a system and method for smart tracking and accountability to reduce construction waste.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

Implementations of the disclosure relate to smart tracking and accounting to reduce construction waste. The method includes obtaining a blueprint for a construction project, the blueprint including a set of locations, a set of material dimensions, and a set of material types. The method further includes, for each of the set of material types, obtaining one or more pieces of materials for the construction project, each piece of material having a standard dimension. The method further includes determining one or more cut specifications for a piece of material of the one or more pieces of materials of standard dimensions based on the blueprint. The respective portions of the piece of material are associated with a respective location of the set of locations. The method further includes displaying the one or more cut specifications, each portion of the piece of material, and the respective location associated with each portion and enabling a user, using a graphic user interface (UI) of an application that determines and displays the one or more cut specifications and locations associated with each portion of the piece of material, to cut the piece of material such that the piece of material is maximally utilized between the set of locations.

In some implementations, the method further includes physically marking the piece of material according to the one or more cut specifications.

In some implementations, obtaining one or more pieces of materials for the construction project includes providing the blueprint as input to a first artificial intelligence (AI) model trained to determine one or more pieces of materials of standard dimensions and a set of build actions based on a blueprint and obtaining, from the first AI model, one or more outputs including an indication of the one or more pieces of materials of standard dimensions and a set of build actions including the one or more cut specifications.

In some implementations, determining the one or more cut specifications for the piece of material of the one or more pieces of materials of standard dimensions based on the blueprint includes providing the blueprint as input to a second artificial intelligence (AI) model trained to determine a set of cut specifications and a location associated with each portion of a piece of material based on a blueprint and obtaining, from the second AI model, one or more outputs including an indication of the one or more cut specifications and a location of the set of locations associated with each portion of the piece of material.

In some implementations, the UI includes at least one of the one or more cut specifications, one or more dimensions of the piece of material, the respective portions of the piece of material, or respective locations associated with each respective portion of the piece of material.

In some implementations, the method further includes maintaining a progress indicator for a subset of the one or more pieces of materials of a same type and dimension that are associated with a same cut specification.

In some implementations, the method further includes generating a list of the one or more cut specifications ordered such that the piece of material is maximally utilized.

In some implementations, the piece of material is associated with an inventory identifier.

In some implementations, each of the respective portions of the piece of material are associated with a respective material identifier.

In some implementations, the method further includes receiving, via the UI of a client device, an indication that a construction-related action corresponding to the one or more cut specifications is performed and updating an inventory associated with the construction project based on the indication.

In some implementations, the method further includes updating an efficiency metric associated with the user based on the indication.

In some implementations, the method further includes updating a progress metric associated with the construction project based on the indication.

### BRIEF DESCRIPTION OF THE DRAWINGS

The accompanying drawings, which are incorporated herein and form a part of the specification, illustrate the disclosure and, together with the description, further serve to explain the principles of the disclosure and to enable a person skilled in the pertinent art to make and use the disclosure. The disclosure is illustrated by way of examples, and not by way of limitation, in the figures of the accompanying drawings. Note that the components of the drawings may not be drawn to scale.

FIG. 1 illustrates a system for smart tracking and accounting to reduce construction waste, in accordance with some embodiments of the disclosure.

FIG. 2 illustrates a graphical user interface (GUI) for a smart tracking and accounting application, in accordance with some embodiments of the disclosure.

FIG. 3 illustrates building material with physical markings indicating where to cut, in accordance with some embodiments of the disclosure.

FIG. 4 is a flow diagram of an example method for smart tracking and accounting to reduce construction waste, in accordance with embodiments of the disclosure.

FIG. 5 is a block diagram of an example computer system in which embodiments of the present disclosure may operate.

### DETAILED DESCRIPTION

The present disclosure describes systems and methods for smart tracking and accounting of construction material usage to reduce construction waste. Because construction materials usually come in standard dimensions (e.g., a board being a certain length), it is likely that there will be a portion of material left over that has no other place or destination to be utilized. That leftover portion is often thrown out as construction waste. Additionally, excessive waste can be directly caused by human inefficiencies, unaccountability, and poor design. This disclosure offers a solution to eliminate excessive waste cumulated at the end of a construction project. The proprietary software application described here allows every piece of construction material to be tracked in an accurate and efficient manner and holds all users accountable for their material usage.

Embodiments of the present disclosure will now be described in detail with reference to the drawings, which are provided as illustrative examples so as to enable those skilled in the art to practice the embodiments. Notably, the figures and examples below are not meant to limit the scope to a single embodiment, but other embodiments are possible by way of interchange of some or all of the described or illustrated elements. Wherever convenient, the same reference numbers will be used throughout the drawings to refer to same or like parts. Where certain elements of these embodiments can be partially or fully implemented using known components, only those portions of such known components that are necessary for an understanding of the embodiments will be described, and detailed descriptions of other portions of such known components will be omitted so as not to obscure the description of the embodiments. In the present specification, an embodiment showing a singular component should not be considered limiting; rather, the scope is intended to encompass other embodiments including a set of the same component, and vice-versa, unless explicitly stated otherwise herein. Moreover, applicants do not intend for any term in the specification or claims to be ascribed an uncommon or special meaning unless explicitly set forth as such. Further, the scope encompasses present and future known equivalents to the components referred to herein by way of illustration.

Implementations of the present disclosure describe a smart tracking and accounting method to reduce construction waste. Processing logic can manage materials for a construction project by determining cut specifications for materials and associating each piece of material with a destination (e.g., a location and/or room of the construction project where the material will be used). Processing logic can also track build actions (e.g., actions performed on the material as part of the construction, such as cutting the material) to be performed on each material used in the construction project. For example, in some embodiments the processing logic can obtain (e.g., via a UI of a client device) a blueprint associated with the construction project and determine one or more material types and quantities, material destinations for each piece of material, cut specifications (e.g., indications of where to cut the material to create components that satisfy blueprint criteria), and build actions (e.g., actions performed to progress the project, such as cutting, welding, framing, etc.). The processing logic can display cut specifications, associated destinations, and/or build actions via the UI of the client device and receive notifications indicating when a build action is complete. Upon receiving such a notification, the processing logic can update information associated with an inventory of the materials and information regarding the progress of the build (e.g., individual user data, overall project completion data) based on the completed build action.

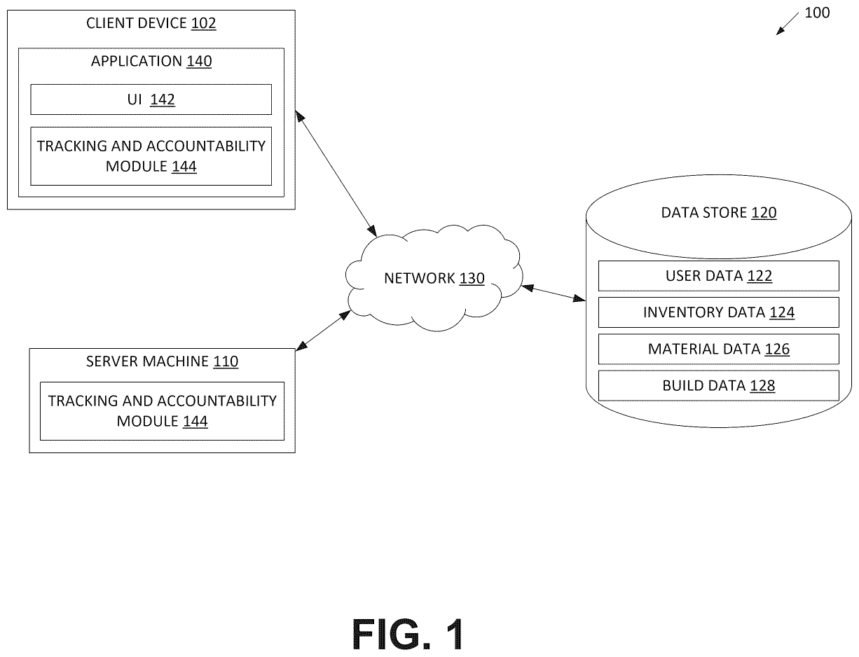

FIG. 1 illustrates a system for smart tracking and accounting to reduce construction waste, in accordance with some embodiments of the disclosure. The system 100 can include a client device 102, a server machine 110, and a data store 120 connected to network 130, in some embodiments. A single client device 102, server machine 110, and data store 120 are shown for purposes of illustration rather than limitation, one or more client devices, server machines, and/or data stores can be implemented in some embodiments.

In some embodiments, network 130 can include a public network (e.g., the Internet), a private network (e.g., a local area network (LAN) or wide area network (WAN)), a wired network (e.g., Ethernet network), a wireless network (e.g., an 802.11 network or a wireless fidelity (Wi-Fi) network), a cellular network (e.g., a Long Term Evolution (LTE) network), routers, hubs, switches, server computers, and/or a combination thereof.

In some implementations, data store 120 is a persistent storage that is capable of storing data as well as data structures to tag, organize, and index the data. Data can include user data 122, inventory data 124, material data 126, and/or build data 128, in accordance with embodiments described herein. User data 122 can include information on the role of a user (e.g., cutter, builder, painter, etc.) and the progress of the user (e.g., the amount of work completed, the average efficiency of the worker). Inventory data 124 can include information on each raw and/or uncut material of standard dimensions (e.g., sizes in which pieces of materials are commonly sold) used in the build (e.g., the quantity of the material, material dimensions, material type). In some embodiments, raw, uncut materials can have an inventory identification number that corresponds to the dimensions and type of material. For example, an inventory identification number can be associated with all uncut wooden boards of the same dimensions and material type to track the amount of the uncut wooden boards in the inventory. Material data 126 can include information on cut materials (e.g., material size, the quantity of the material, the destination associated with the material). In some embodiments, each cut material can be associated with a unique identifier (e.g., an identification number) used to track the material throughout the project. For example, each cut portion of a wooden board can have a respective unique identification number to determine the destination of each cut portion. Build data 128 can include information on the project progress (e.g., metrics on the amount of work completed, the efficiency of different portions of the project) and/or project design data (e.g., blueprints, a list of tasks to complete the project, cut specifications). Data store 120 can be hosted by one or more storage devices, such as main memory, magnetic or optical storage based disks, tapes or hard drives, NAS, SAN, and so forth.

Client device 102 can include one or more computing devices such as personal computers (PCs), laptops, mobile phones, smart phones, tablet computers, netbook computers, network-connected televisions, etc. In some embodiments, one or more client devices (e.g., client device 102) can be located in a fabrication facility (i.e., a facility where raw materials are cut, shaped, and/or assembled) and/or a construction site. For example, a first client device can be located in a fabrication facility to perform a first build action (e.g., cut a material according to cut specifications) and a second client device can be located at a construction site to track the completion of the first build action and/or perform a second build action (e.g., install a material at an indicated destination). As stated above, one or more client devices can be implemented depending on the embodiment.

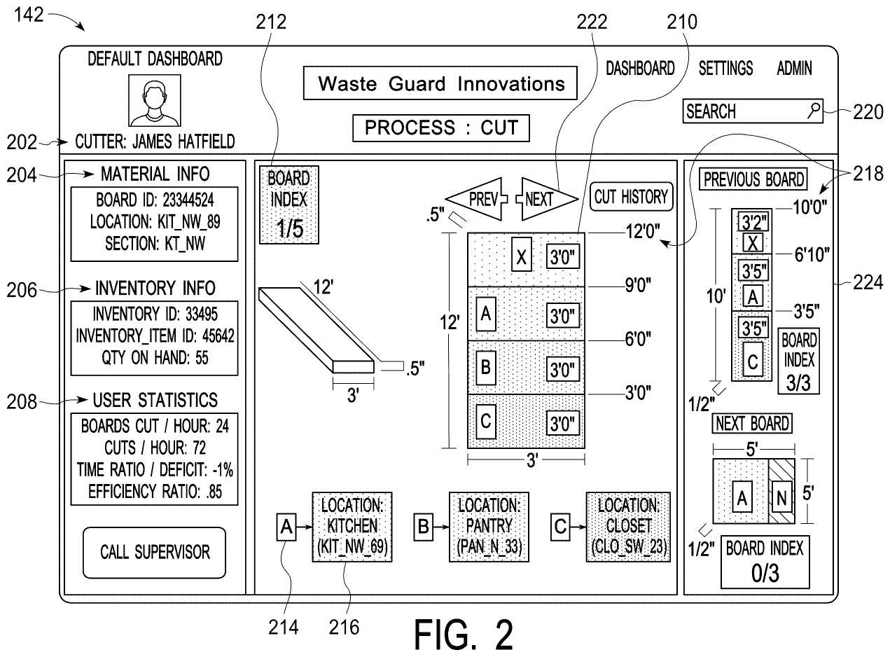

In some embodiments, client device 102 can be connected to the system 100. In some embodiments, client device 102 can present (e.g., display) a user interface (UI) 142 to a user of a respective client device through application 140. The client device 102 can also collect input from users through input features. For example, a user can provide one or more updates on the inventory and/or indications of the completion of a build action via a client device 102. Further details regarding the UI 142 of the application are described in FIG. 2.

The client device 102 can also execute a version of application 140 for tracking construction materials and worker progress. Application 140 can include a tracking and accountability module 144, in some embodiments. Application 140 can also be configured to communicate (e.g., via network 130) with a server machine 110, in some embodiments. Depending on the embodiment, server machine 110 can be one or more computing devices (such as a rackmount server, a router computer, a server computer, a personal computer, a mainframe computer, a laptop computer, a tablet computer, a desktop computer, etc.), data stores (e.g., hard disks, memories, databases), networks, software components, or hardware components that can be used to provide a user with access to one or more data items of the data store 120. For example, the server machine 110 can store the back-end portion of application modules (e.g., tracking and accountability module 144). As such, application 140 can send a request for information to server machine 110, which can retrieve the requested information (e.g., from data store 120) and provide it to the client device 102 for presentation via the UI 142. It should be noted that tracking and accountability module 144 is used for exemplary purposes, and the module may be divided into additional modules. In some embodiments, one or more modules may reside on different computing devices (e.g., server computers, client devices, etc.).

The tracking and accountability module 144 can manage material use and inventory, track user and project efficiency, and determine an optimal workflow for the project, in some embodiments. To manage material use and inventory, the tracking and accountability module 144 can track inventory data 124 and material data 126 for a project. For example, tracking an accountability module 144 can maintain an inventory table of each raw and/or uncut material to be used in the project, including the type of material (e.g., wood, metal), description of the object (e.g., a board or a pipe, size dimensions, etc.), and quantity of the material. The tracking and accountability module 144 can also maintain a material table of each piece of material (e.g., cut portions of material) that includes the type of material, a destination where the material is intended to be used (e.g., a room the material will be used to build, such as kitchen, bedroom, etc.), and/or a description of the piece of material. As stated above, raw and/or uncut materials can have an inventory identifier to track the quantity of the materials and pieces of materials can have unique identifiers to determine the destination associated with the piece.

In some embodiments, the tracking and accountability module 144 can maintain a table of build actions to be performed on each material (e.g., stored in build data 128). Build actions are tasks to be performed on a material to progress the project, such as cutting a wood board to make it a desired size. Depending on the embodiment, the build actions can be ordered in a way to maximize the efficiency of the project (e.g., actions to create components that are used earlier in a build, such as support beams, can be prioritized and listed above actions that create components used later in the build, such as trim or other finishes). The table can also include an indication of whether each build action is completed. For example, the tracking and accountability module 144 can identify a build action (e.g., in the table of build actions in build data 128) to cut a steel beam according to a set of cut specifications and check if a bit indicator associated with the build action is set to a value indicating that the steel beam has been cut. In some embodiments, a timestamp indicating when the build action was performed, a location where the build action was performed, and/or a user who performed the build action can be included in the build data 128. Based on the completed build action, the tracking and accountability module 144 can update the inventory data 124 and/or material data 126 with the quantity and/or location of the material.

In some embodiments, materials can be identified using a physical indicator. For example, in some embodiments, materials can include an encoded label (e.g., a two-dimensional bar code, such as a quick response (QR) code) that corresponds to the inventory identifier and/or material identifier to manage the inventory and track the material. In an illustrative example, an uncut wooden board with a QR code can arrive at a fabrication facility to be cut. When the QR code is scanned (e.g., via an imaging component, such as a camera, on a client device 102), the tracking and accountability module 144 can update the location of the wooden board to be the fabrication facility. In some embodiments, the QR code can also be used to determine which material is used in a build action (e.g., by scanning the wooden board before cutting it), which the tracking and accountability module 144 can use to update the inventory data 124. In other embodiments, each piece of a material can have an encoded label, which can be scanned to determine the destination of the material and sort it accordingly. For example, each piece of a wooden board can have a separate encoded label corresponding to its unique identifier, which is used to determine the destination of and track the location of the piece.

In some embodiments, the tracking and accountability module 144 can perform blueprint parsing (e.g., analyze a blueprint to extract information) to determine pieces of materials (e.g., materials of standard dimensions) to use and/or build actions (e.g., cut specifications) to perform based on a blueprint. For example, in some embodiments, the tracking and accountability module 144 can obtain a blueprint (e.g., via the UI 142 of a client device 102) and identify information regarding the dimensions (e.g., wall length, slab thickness, etc.), structural layout (e.g., number and spacing of beams, roofing and flooring systems), and material types (e.g., wood, concrete, steel) to determine the type and quantity of materials to be used in the construction project. For example, the tracking and accountability module 144 can identify portions of the build that use the same type of wood board (e.g., same type of wood, same board thickness) to calculate how much of the wood board is used in the construction project. In some embodiments, the tracking and accountability module 144 can then determine one or more cut specifications (e.g., indications of where to cut) for the wood board to optimize resource use and minimize waste by increasing the amount of the wood board that is used. For example, the tracking and accountability module 144 can identify where to cut the wood board to create multiple wood boards that satisfy size criterion (e.g., size specifications in the blueprint) to be used in the project and reduce the amount of the wood board that is discarded.

Additionally, the tracking and accountability module 144 can determine the amount of waste generated by calculating the number and size of materials that are discarded according to the cut specifications. In some embodiments, the tracking and accountability module 144 can increase resource usage by determining one or more cut specifications that generate the least amount of waste (e.g., where the total amount of discarded material is the smallest in number and/or size). For example, the tracking and accountability module 144 can determine to cut a wooden board horizontally rather than vertically to maximize the amount of the board that is utilized rather than discarded and update one or more cut specifications for the wooden board accordingly.

In some embodiments, each portion of a material can be associated with a destination (e.g., a room where the build material will be used). The tracking and accountability module 144 can determine a destination associated with each portion based on the blueprint, in some embodiments. For example, the tracking and accountability module 144 can associate a piece of a wooden board with a kitchen based on a blueprint indicating that the kitchen will include wooden boards of the same size and type of wood as the piece of the wooden board. In some embodiments, the tracking and accountability module 144 can determine the destination of each material based on an architectural layout (e.g., floor plan) included in the blueprint and/or associated with the blueprint. For example, a blueprint can include labeled rooms with dimensions and materials of components used in each room, such the materials and dimensions for a wall in a room indicated to be a kitchen. The tracking and accountability module can determine the type and amount of materials used to build the wall and associate each identified material with the kitchen, which is the intended destination for the materials to be used.

In some embodiments, the tracking and accountability module 144 can use a building information modeling (BIM) model, an artificial intelligence (AI) model, and/or an external service (e.g., application programming interface, tool, etc.) to determine the materials, build actions, and/or destinations associated with each portion of the materials based on a blueprint. For example, the tracking an accountability module 144 can provide the blueprint as input to an AI model trained to identify materials for a construction based on a blueprint and obtain one or more outputs of the AI model, including information indicating the materials for the project. Depending on the embodiment, more than one model may be used to determine the materials, destinations associated with portions of each material, and/or build actions to perform. Using the example above, a first AI model can be used to determine the materials for the project. The tracking and accountability module 144 can provide the blueprint and/or determined materials to a separate model (e.g., a second AI model) trained determine cut specifications and to match cuts in the cut specifications to destinations based on the blueprint. The tracking and accountability module 144 can then obtain an output from the separate model including information indicating the cut specifications and associated destinations of each portion of the materials.

In some embodiments, the tracking and accountability module 144 can determine an optimized cutlist, or a list containing the measurements of a material to cut (e.g., cut specifications) in an order to improve efficiency during construction. The cutlist can be generated based on cut specifications, material quantities and types for the build, material destinations, and/or build actions, in some embodiments. For example, if the blueprint indicates that boards for subfloor sheathing are installed before boards for finish flooring, tracking and accountability module 144 can prioritize creating the boards for subfloor sheathing by listing the build actions to cut those boards higher on the cutlist than the boards for the finish flooring. In other embodiments, tracking and accountability module 144 can determine the list based on the function of the material. For example, tracking and accountability module 144 can determine whether a material is used for a structural purpose (e.g., a beam, stud, joist) or for finishing (e.g., siding, baseboard, trim) to determine the order in which to cut the material, as structural components are used before components for finishing. In some embodiments, the tracking and accountability module 144 can update the inventory data 124 and build data 128 with the amount of materials, cut specifications, and cutlist after they are determined and as build actions are completed.

In some embodiments, the tracking and accountability module 144 can determine whether a document is approved before proceeding to perform operations using the document and/or action. For example, in some embodiments, a blueprint can be associated with one or more users who are to review and approve the blueprint before it is used in a construction project. The blueprint can be associated with one or more flags (e.g., bit indicators) corresponding to each user to indicate whether the user has approved the blueprint. Upon receiving an indication that a user has reviewed and approved the blueprint (e.g., via the UI 142 of the client device 102), the tracking and accountability module 144 can update the corresponding bit indicator to indicate the user has approved the blueprint. In other embodiments, the tracking and accountability module 144 can maintain a table of each document, the associated reviewers, and an indication of whether each associated reviewer has approved the document. Upon determining that all the reviewers have approved the blueprint, the tracking and accountability module 144 can proceed to parse the blueprint and extract information on materials and cut specifications.

To track user and project efficiency, the tracking and accountability module 144 can monitor how long it takes to perform a build action. For example, in some embodiments, the tracking and accountability module 144 can determine the passage of a specified time interval and send a notification to be displayed via the UI 142 of the client device 102 that requests an update on the status of a build action (e.g., a request to indicate what build action is currently being performed). Such notifications allow the tracking and accountability module 144 to accurately track the status of the project by periodically updating build data 128 with received status information. In other or similar embodiments, the tracking and accountability module 144 can include a timer that tracks the time from when a build action is started (e.g., when a UI component is interacted with to indicate the build action has started) to when the build action is completed. The tracking and accountability module can use the timer to determine an efficiency metric for the user (e.g., an efficiency ratio, such as the amount of time it took the worker to complete the build action compared to an average time to complete the build action), which can be included in user data 122 corresponding to the user. The timer can also be used to identify possible delays in a project by comparing the measured time to complete a build action with an expected time. Identifying delays early can allow action to be taken to determine and address problems causing the delay or to modify future build actions to accommodate for the delay.

In some embodiments, the tracking and accountability module 144 can provide progress reports based on the type of user. User data 122 can include information corresponding to each user, such as the type of role the user has in the project (e.g., cutter, builder, manager, administrator, etc.), the tasks (e.g., build actions) that are performed by and/or assigned to the user, the efficiency of the user (e.g., the efficiency ratio), and/or the administrative access of the user. As such, the tracking and accountability module 144, can determine the type of role a user has and provide a progress report based on the role. For example, a tradesman (e.g., a cutter, builder, etc.) can receive a progress report indicating the amount of build actions assigned to the role that have been completed, while a project manager can receive a progress report on overall project status and efficiency (e.g., project progress metrics, such as the amount of build actions completed). Additionally, in some embodiments, the user data can track the status of the most recent build action performed by a user. For example, the tracking and accountability module 144 can receive a notification (e.g., via the UI of the client device) that a build action a user is working on is incomplete and store the user progress (e.g., the incomplete build action) in the user data 122. When the tracking and accountability module 144 determines that the same user has logged in, the incomplete build action can be sent to the client device 102 to be performed by the same user.

FIG. 2 illustrates a graphical user interface for a smart tracking and accounting application, in accordance with some embodiments of the disclosure. The example UI (e.g., UI 142) is one that can be displayed via a client device 102 after a user is authenticated. As seen in the example, in some embodiments, the UI 142 can include various visual elements (e.g., UI elements) and regions, and can be a mechanism by which the user engages with the system 100 at large. In some embodiments, the UI 142 can include multiple visual elements and regions that enable presentation of information, for decision-making, content delivery, etc. at a client device 102. Note that while specific dimensions are shown in the example UI shown in FIG. 2 for illustrative purposes, the scope of the disclosure is not limited to specific dimensions or material type of a piece of construction material (e.g., a wooden board, a steel plank, a polyvinyl chloride (PVC) pipe, etc.).

In some embodiments, the UI 142 and/or client device 102 can include input features to intake information from a client device 102. In one or more examples, a user of client device 102 can provide input data (e.g., a user query, control commands, etc.) into an input feature of the UI 142 or client device 102, for transmission to the system 100 at large. Input features of UI 142 and/or client device 102 can include space, regions, or elements of the UI 142 that accept user inputs. For example, input features may include visual elements (e.g., GUI elements) such as buttons, text-entry spaces, selection lists, drop-down lists, etc. For example, in some embodiments, input features may include a text box which a user of client device 102 can use to input textual data. The application 140 via client device 102 can then transmit the textual data to the system 100 at large, for further processing (e.g., by tracking and accountability module 144). For example, the UI can include a search bar 220 where a user can input a search query for materials, inventory information, destination locations, and/or documents (e.g., blueprints). The tracking and accountability component 144 can then access data store 120 to retrieve the requested information. In other examples, input features can include a selection list and/or a button, in which a user of client device 102 can input selection data (e.g., by selecting, or clicking). The application 140 via client device 102 can then transmit that selection data to the system 100 at large, for further processing. For example, selecting the next button 222 can indicate that a build action to cut a board is complete, upon which the tracking and accountability module 144 can update the inventory and provide a new build action (e.g., a new cut specification) to be displayed via the UI 142. In other embodiments, the next and/or previous button can open a new page (e.g., a popup window) that displays the cut specifications for the next and/or previous pieces of materials according to a cutlist. In other or similar embodiments, the UI 142 can include buttons that correspond to navigation links, such as dashboard, setting, and/or administration links, as displayed in the top right corner of the UI 142. It should be noted that the displayed navigation links are for illustrative purposes and can vary based on the embodiment. For example, in some embodiments the navigations links can vary based on the role of a user, so a tradesman may not have an administration link to manage other workers, while a project manager may have the administration link to manage the workers they supervise.

In some embodiments, the UI 142 can display the role 202 associated with a user (e.g., cutter, manager, etc.). For example, in FIG. 2 the role 202 of “cutter” is displayed. In some embodiments, the name and/or user icon (e.g., an avatar or image depicting a user) corresponding to the user can be displayed in addition to the role 202. In other or similar embodiments, a user can have a unique identifier number (e.g., worker identification number), which can also be displayed. Information regarding the role of the user can be retrieved from user data 122 in data store 120, in some embodiments. In other or similar embodiments, the UI 142 can include material information 204, inventory information 206, and/or user statistics 208. Material information 204 can include a unique identification number associated with the piece of material and the destination of the piece of material, in some embodiments. For example, “KIT_NW_69” indicates that the board will be used as part of the northwest wall of the kitchen and is board #69 in that section. The destination information can be used to sort a piece of material after it is subject to a build action (e.g., after it is cut). Using the example above, after being cut, the piece of the board associated with the kitchen can be placed in a designated location (e.g., a bin, rack, staging area) for materials to be delivered to the kitchen for use. Material information can be stored in material data 126, in some embodiments.

Inventory information 206 can correspond to the uncut piece of material of a standard dimension (e.g., the 12-foot by 3-foot by 5-inch board that is being cut into smaller boards). The inventory information 206 can include two identification numbers: an inventory ID that corresponds to all materials of the same type and size and a unique inventory item ID that corresponds to the specific uncut material. For example, the inventory ID can be associated with all uncut wooden boards of the same material and size, whereas the inventory item ID corresponds to a specific uncut wooden board of the material and size. In some embodiments, the inventory information can also include the quantity of the uncut material in the inventory. Inventory information can be stored in inventory data 124 and updated by the tracking and accountability module 144 based on each build action marked as completed, in some embodiments. For example, after the displayed build action is completed, the tracking and accountability module 144 can update the inventory data 124 to reduce the quantity to 54 wooden boards of the same size and type.

User statistics 208 include information corresponding to the efficiency of the user, such as the amount of work completed per hour, a time ratio deficit (e.g., a difference between an expected time to complete a task and the actual time taken), and/or an efficiency ratio. The amount of work completed per hour can be determined using a timer or by sending a notification after the passage of a specified time interval, in some embodiments. For example, using a timer, the tracking and accountability module can determine how many build actions were marked as complete during each hour and calculate an average of build actions completed per hour. The tracking and accountability module 144 can determine the time ratio deficit by comparing the actual time taken (e.g., captured using a timer) to an expected time to complete a build action. A positive number can indicate that the actual time taken exceeds the expected time, while a negative number can indicate that the actual time taken is below the expected time, in some embodiments. In other or similar embodiments, the user statistics can also include an efficiency ratio, as described above in FIG. 1. The user statistics 208 can be stored in user data 122, in some embodiments.

In some embodiments, the UI 142 can include a diagram indicating cut specifications 210, or the total of all cuts needed to make on a single unit of material (i.e. a board). Each cut specification only applies to a single piece of material (e.g., a board, a pipe, etc.) and contains all cuts to be performed on the material. In some embodiments, the cut specification can include an indication (e.g., a letter indicator 214, a pattern indicator 216) of the destination associated with each portion of the material. For example, the letter “A” and pattern in the cut specification 210 indicate that the identified portion of the board is meant for the kitchen, as indicated by a key at the bottom of the UI 142. In some embodiments, one or more indicators can be used to indicate portions of the piece of material that will be discarded. For example, the letter “X” and corresponding pattern in the cut specification 210 can indicate that the identified portion will not be used in the construction project. It should be noted that letters and patterns (e.g., dots, lines, etc.) are examples of possible indicators, and that other embodiments can include other types and/or combinations of indicators such as numbers, shapes, symbols, and/or colors. The cut specification 210 can also include running measurement indicators 218 to represent the running total of material with all the expected cuts applied. In some embodiments, the cut specification can display the dimensions (e.g., the standard dimensions) of the piece of material. For example, the cut specification 210 indicates that the board is 12 feet long, 3 feet wide, and 5 inches thick. It should be noted that the listed dimensions are for illustrative purposes and can vary based on the piece of material. For example, the cut specifications indicated in the cutlist 224 display pieces of materials with different dimensions, such as the cut specifications for the next piece of material that is 5 feet long, 5 feet wide, and half an inch thick. In some embodiments, the cut specification can include a visual representation (e.g., a 3-dimensional diagram) of the piece of material that displays the dimensions of the piece of material, as shown in the UI 142 to the left of the cut specification 210.

In some embodiments, the UI 142 can include a progress indicator (e.g., board index 212) to indicate when a group of cut specifications 210 is applied to more than a single piece of material. Construction projects can use multiple components of the same material and dimensions (e.g., floorboards of the same size and material). As such, some materials of the same type and dimensions can have the same cut specifications to create similar components. In some embodiments, the tracking and accountability component 144 can group such materials in a cut series (e.g., a group of similar materials with the same cut specifications). The UI 142 can display a material index (e.g., board index 212) that includes the total number of pieces of materials in the cut series and an indication of how many pieces within the cut series have already been cut. In some embodiments, the board index 212 can be displayed as a fraction. For example, in the board index 212 includes the fraction “⅕,” which indicates that there are 5 pieces of material in the cut series and that one piece has already been cut. In some embodiments, the UI 142 can also include a portion of a cutlist 224 indicating one or more cut specifications to make after the cuts corresponding to current cut specifications are completed (e.g., the “Next Board”) and/or one or more cut specifications that have been completed (e.g., the “Previous Board”).

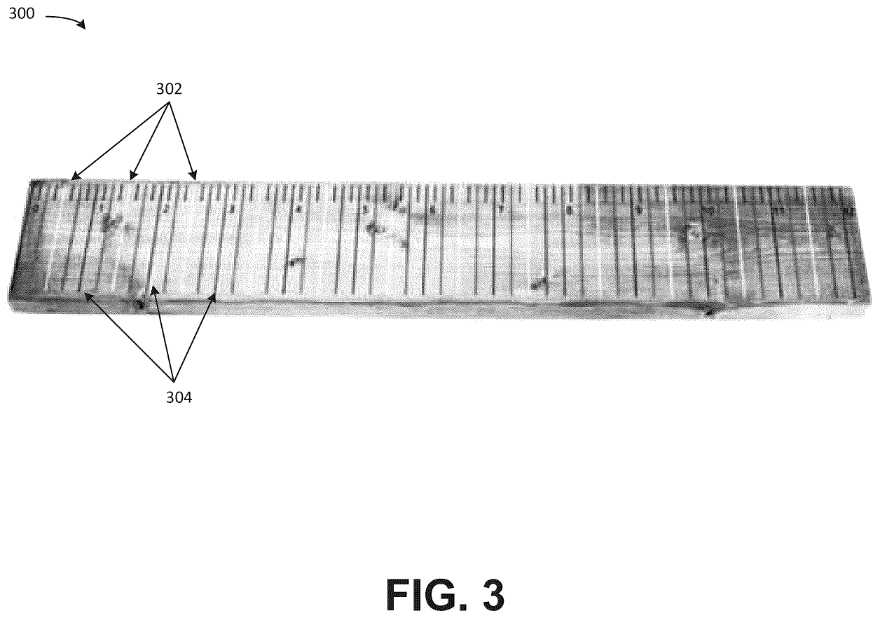

FIG. 3 illustrates building material with physical markings indicating where to cut, in accordance with some embodiments of the disclosure. In some embodiments, physical markings can be made on the material based on the cut specifications determined by the tracking and accountability module 144. This is indicated by wooden board 300, which includes two types of lines: white lines 302 and dark lines 304, indicating different places to cut. Though a wooden board is illustrated in the example, other embodiments can include placing physical markings on other types of materials, such as steel pipes.

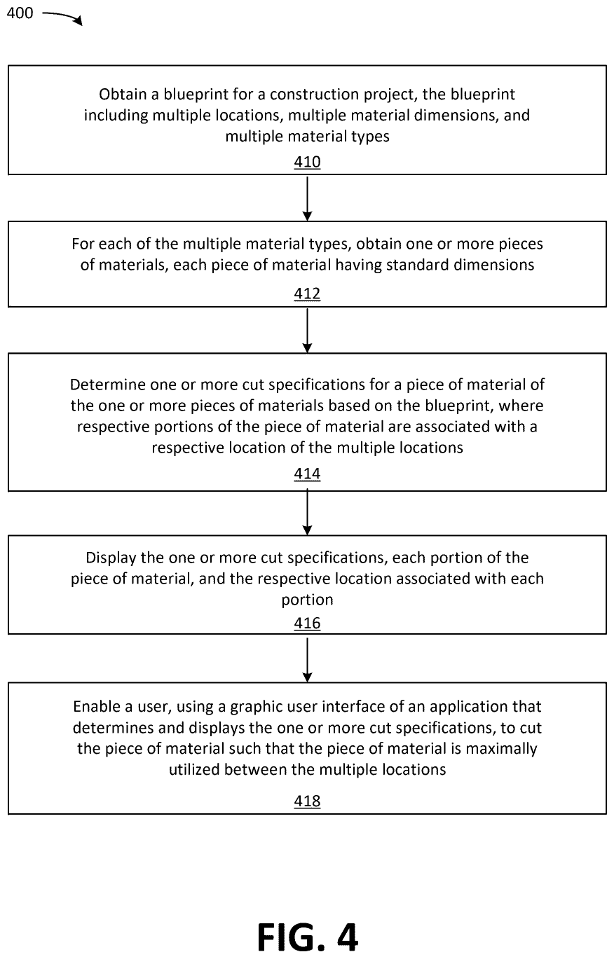

FIG. 4 is a flow diagram of an example method for smart tracking and accounting to reduce construction waste, in accordance with embodiments of the disclosure. The method 400 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 400 is performed by tracking and accountability module 144 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 410, processing logic obtains a blueprint for a construction project. The blueprint includes multiple locations (e.g., destinations), multiple material dimensions, and multiple material types, in some embodiments. Locations refer to rooms and/or portions of the construction project (e.g., a kitchen, cabinet, bedroom, etc.). In some embodiments, the blueprint can include dimensions and material types of structural elements (e.g., walls, floors) in a location, which are used to determine the material dimensions and material types for materials. For example, the blueprint can include a wall of a room and indicate the dimensions of the wall and the type of material the wall is built with. In some embodiments, the blueprint can be received via a UI (e.g., UI 142) of a client device 102. In other or similar embodiments, the tracking and accountability module 144 can determine whether a blueprint is approved for use by one or more users before the blueprint is used for the construction project, as described in FIG. 1.

At operation 412, processing logic obtains one or more pieces of material of standard dimensions (e.g., dimensions at which pieces of materials are commonly sold) for each of the multiple material types. The one or more pieces of materials can be obtained from a vendor or manufacturer, in some embodiments. In some embodiments, the one or more pieces of materials to obtain can be determined using a BIM model, an AI model, and/or an external service, as described in FIG. 1. For example, the tracking and accountability module 144 can provide the blueprint as input to a model and obtain an output including the one or more pieces of materials of standard dimensions for the construction project. In some embodiments, the tracking and accountability module 144 uses an inventory identifier (e.g., identification number) for the same pieces of materials (e.g., materials of the same dimensions and material type) to determine the quantity of each material in the inventory.

At operation 414, processing logic determines one or more cut specifications for a piece of material of the one or more pieces of materials of standard dimensions based on the blueprint. Each respective portion of the piece of material is associated with a respective location (e.g., destination) of the set of locations. In some embodiments the respective location associated with each portion of the material can be determined using an AI model, as described in FIG. 1. In other or similar embodiments, each portion of the material has a unique identifier (e.g., a material identification number), which the tracking and accountability module can use to determine the destination associated with the portion of material. In some embodiments, the one or more cut specifications can be included in a cutlist, which lists each cut in one or more cut specifications in an order that will maximize the efficiency of the construction project, as described in FIG. 1.

At operation 416, processing logic displays the one or more cut specifications, each portion of the piece of material, and the respective location associated with each portion. In some embodiments, the display can be via a UI (e.g., UI 142) of an application (e.g., application 140) on a client device (e.g., client device 102). At operation 418, processing logic enables a graphic UI (e.g., UI 142) of an application (e.g., application 140) that determines and displays the one or more cut specifications and locations associated with each portion of the piece of material, to cut the piece of material such that the piece of material is maximally utilized between the set of locations. The UI 142 can include cut specifications, dimensions of materials and portions of materials, and/or the destinations associated with each portion of the materials, as described in FIG. 2. In some embodiments, the one or more materials can be physically marked according to the cut specifications displayed via the UI 142 to indicate where to cut, as described in FIG. 3.

In some embodiments, the tracking and accountability module 144 can receive an indication (e.g., via the UI 142) of when a build action is complete and update user data 122 (e.g., updating an efficiency ratio associated with a user), inventory data 124 (e.g., updating the quantity of inventory), material data 126 (e.g., updating the quantity and/or location of materials), and/or build data 128 (e.g., updating a progress and/or efficiency metric of the construction project) accordingly, as described in FIG. 1. Additionally, in some embodiments, the UI 142 can include a progress indicator such as a board index for sets of the same material with the same cut specifications (e.g., wooden boards of the same dimensions that will be cut in the same way).

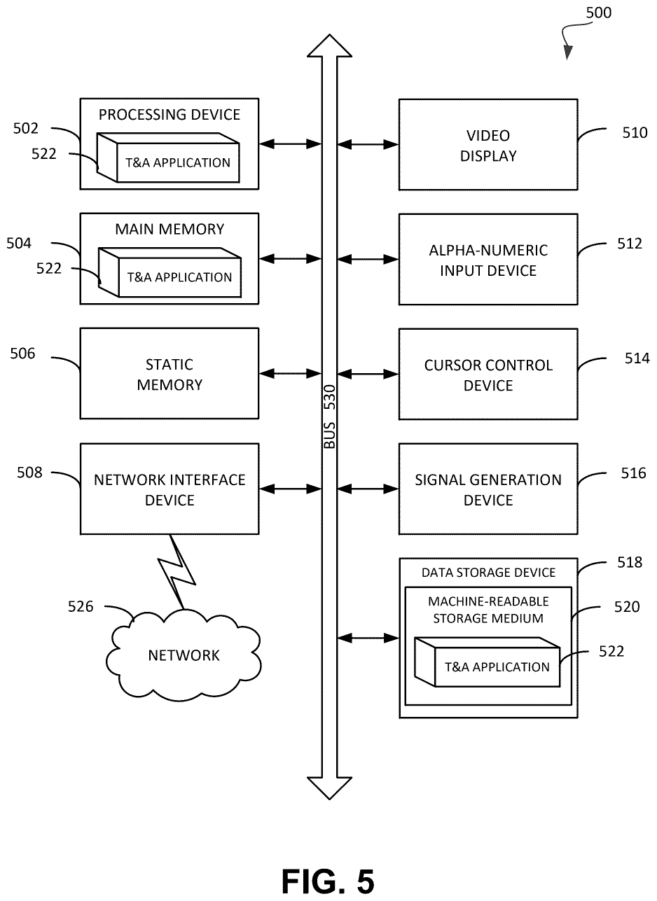

FIG. 5 illustrates a diagrammatic representation of a machine in the exemplary form of a computer system 500 within which a set of instructions, for causing the machine to perform any one or more of the methodologies discussed herein, may be executed. In alternative embodiments, the machine may be connected (e.g., networked) to other machines in a local area network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a personal digital assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein.

The exemplary computer system 500 includes a processing device 502, a main memory 504 (e.g., read-only memory (ROM), flash memory, dynamic random access memory (DRAM) (such as synchronous DRAM (SDRAM) or Rambus DRAM (RDRAM), etc.), a static memory 506 (e.g., flash memory, static random access memory (SRAM), etc.), and a data storage device 518, which communicate with each other via a bus 530.

Processing device 502 represents one or more general-purpose processing devices such as a microprocessor, central processing unit, or the like. More particularly, the processing device may be complex instruction set computing (CISC) microprocessor, reduced instruction set computer (RISC) microprocessor, very long instruction word (VLIW) microprocessor, or processor implementing other instruction sets, or processors implementing a combination of instruction sets. Processing device 502 may also be one or more special-purpose processing devices such as an application specific integrated circuit (ASIC), a field programmable gate array (FPGA), a digital signal processor (DSP), network processor, or the like. Processing device 502 is configured to execute the tracking and accountability (T&A) application 522 for performing the operations and steps discussed herein.

Computer system 500 may further include a network interface device 508. Computer system 500 also may include a video display unit 510 (e.g., a liquid crystal display (LCD) or a cathode ray tube (CRT)), an alphanumeric input device 512 (e.g., a keyboard), a cursor control device 514 (e.g., a mouse), and a signal generation device 516 (e.g., a speaker).

Data storage device 518 may include a machine-readable storage medium (or more specifically a computer-readable storage medium) 520 having one or more sets of instructions embodying any one or more of the methodologies of functions described herein. The T&A application 522 may also reside, completely or at least partially, within main memory 504 and/or within processing device 502 during execution thereof by computer system 500; main memory 504 and processing device 502 also constituting machine-readable storage media. The T&A application 522 may further be transmitted or received over a network 526 via network interface device 508.

Machine-readable storage medium 520 may also be used to store the T&A application 522 persistently. While machine-readable storage medium 520 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instruction for execution by the machine and that causes the machine to perform any one or more of the methodologies of the disclosure. The term “machine-readable storage medium” shall accordingly be taken to include, but not be limited to, solid-state memories, and optical and magnetic media.

The components and other features described herein can be implemented as discrete hardware components or integrated in the functionality of hardware components such as ASICs, FPGAs, DSPs or similar devices. In addition, these components can be implemented as firmware or functional circuitry within hardware devices. Further, these components can be implemented in any combination of hardware devices and software components.

Some portions of the detailed descriptions are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise, as apparent from the above discussion, it is appreciated that throughout the description, discussions utilizing terms such as “enabling”, “transmitting”, “requesting”, “identifying”, “querying”, “retrieving”, “forwarding”, “determining”, “passing”, “processing”, “disabling”, or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Embodiments of the disclosure also relate to an apparatus for performing the operations herein. This apparatus may be specially constructed for the required purposes or it may include a general purpose computer selectively activated or reconfigured by a computer program stored in the computer. Such a computer program may be stored in a computer readable storage medium, such as, but not limited to, any type of disk including floppy disks, optical disks, CD-ROMs and magnetic-optical disks, read-only memories (ROMs), random access memories (RAMs), EPROMs, EEPROMs, magnetic or optical cards, flash memory devices including universal serial bus (USB) storage devices (e.g., USB key devices) or any type of media suitable for storing electronic instructions, each of which may be coupled to a computer system bus.

The algorithms and displays presented herein are not inherently related to any particular computer or other apparatus. Various general purpose systems may be used with programs in accordance with the teachings herein or it may prove convenient to construct more specialized apparatus to perform the required method steps. The required structure for a variety of these systems will be apparent from the description above. In addition, the disclosure is not described with reference to any particular programming language. It will be appreciated that a variety of programming languages may be used to implement the teachings of the disclosure as described herein.

It is to be understood that the exemplary embodiments are merely illustrative of the disclosure and that many variations of the above-described embodiments may be devised by one skilled in the art without departing from the scope of the disclosure. The scope of the disclosure should, therefore, be determined with reference to the appended claims, along with the full scope of equivalents to which such claims are entitled.

The words “example” or “exemplary” are used herein to mean serving as an example, instance, or illustration. Any aspect or design described herein as “example’ or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or.” In addition, the articles “a” and “an” as used in this application and the appended claims should generally be construed to mean “one or more” unless specified otherwise or clear from context to be directed to a singular form.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment.

The above description is intended to be illustrative and not restrictive. For example, the above-described examples (or one or more aspects thereof) may be used in combination with each other. Other implementations can be used, such as by one of ordinary skill in the art upon reviewing the above description. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed implementation. Thus, the following claims are hereby incorporated into the Detailed Description, with each claim standing on its own as a separate implementation, and it is contemplated that such implementations can be combined with each other in various combinations or permutations. The scope of the implementations of the disclosure should be determined with reference to the appended claims, along with the full scope of equivalents to which such claims are entitled.

In the drawings, which are not necessarily drawn to scale, like numerals may describe similar components in different views. Like numerals having different letter suffixes may represent different instances of similar components. The drawings illustrate generally, by way of example, but not by way of limitation, various implementations discussed in the present document.

What is claimed is:

1. A method comprising:
obtaining a blueprint for a construction project, the blueprint comprising a plurality of locations, a plurality of material dimensions, and a plurality of material types;
for each of the plurality of material types, obtaining one or more pieces of materials for the construction project, each piece of material having a standard dimension;
determining one or more cut specifications for a piece of material of the one or more pieces of materials of standard dimensions based on the blueprint, wherein respective portions of the piece of material are associated with a respective location of the plurality of locations;
displaying the one or more cut specifications, each portion of the piece of material, and the respective location associated with each portion; and
enabling a user, using a graphic user interface (UI) of an application that determines and displays the one or more cut specifications and locations associated with each portion of the piece of material, to cut the piece of material such that the piece of material is maximally utilized between the plurality of locations.

2. The method of claim 1, further comprising:
physically marking the piece of material according to the one or more cut specifications.

3. The method of claim 1, wherein obtaining one or more pieces of materials for the construction project comprises:
providing the blueprint as input to a first artificial intelligence (AI) model trained to determine one or more pieces of materials of standard dimensions and a plurality of build actions based on a blueprint; and
obtaining, from the first AI model, one or more outputs comprising an indication of the one or more pieces of materials of standard dimensions and a plurality of build actions comprising the one or more cut specifications.

4. The method of claim 1, wherein determining the one or more cut specifications for the piece of material of the one or more pieces of materials of standard dimensions based on the blueprint comprises:
providing the blueprint as input to a second artificial intelligence (AI) model trained to determine a set of cut specifications and a location associated with each portion of a piece of material based on a blueprint; and
obtaining, from the second AI model, one or more outputs comprising an indication of the one or more cut specifications and a location of the plurality of locations associated with each portion of the piece of material.

5. The method of claim 1, wherein the UI comprises at least one of the one or more cut specifications, one or more dimensions of the piece of material, the respective portions of the piece of material, or respective locations associated with each respective portion of the piece of material.

6. The method of claim 1, further comprising:
maintaining a progress indicator for a subset of the one or more pieces of materials of a same type and dimension that are associated with a same cut specification.

7. The method of claim 1, further comprising:
generating a list of the one or more cut specifications ordered such that the piece of material is maximally utilized.

8. The method of claim 1, wherein the piece of material is associated with an inventory identifier.

9. The method of claim 1, wherein each of the respective portions of the piece of material are associated with a respective material identifier.

10. The method of claim 1, further comprising:
receiving, via the UI of a client device, an indication that a construction-related action corresponding to the one or more cut specifications is performed; and
updating an inventory associated with the construction project based on the indication.

11. The method of claim 10, further comprising:
updating an efficiency metric associated with the user based on the indication.

12. The method of claim 10, further comprising:
updating a progress metric associated with the construction project based on the indication.

13. A system comprising:
a memory;
a set of processing devices coupled to the memory, wherein the set of one or more processing devices is to perform operations comprising:
obtaining a blueprint for a construction project, the blueprint comprising a plurality of locations, a plurality of material dimensions, and a plurality of material types;
for each of the plurality of material types, obtaining one or more pieces of materials for the construction project, each piece of material having a standard dimension;
determining one or more cut specifications for a piece of material of the one or more pieces of materials of standard dimensions based on the blueprint, wherein respective portions of the piece of material are associated with a respective location of the plurality of locations;
displaying the one or more cut specifications, each portion of the piece of material, and the respective location associated with each portion; and
enabling a user, using a graphic user interface (UI) of an application that determines and displays the one or more cut specifications and locations associated with each portion of the piece of material, to cut the piece of material such that the piece of material is maximally utilized between the plurality of locations.

14. The system of claim 13, wherein the set of one or more processing devices is to perform operations further comprising:
physically marking the piece of material according to the one or more cut specifications.

15. The system of claim 13, wherein obtaining one or more pieces of materials for the construction project comprises:
providing the blueprint as input to a first artificial intelligence (AI) model trained to determine one or more pieces of materials of standard dimensions and a plurality of build actions based on a blueprint; and
obtaining, from the first AI model, one or more outputs comprising an indication of the one or more pieces of materials of standard dimensions and a plurality of build actions comprising the cone or more cut specifications.

16. The system of claim 13, wherein determining the one or more cut specifications for the piece of material of the one or more pieces of materials of standard dimensions based on the blueprint comprises:
providing the blueprint as input to a second artificial intelligence (AI) model trained to determine a set of cut specifications and a location associated with each portion of a piece of material based on a blueprint; and
obtaining, from the second AI model, one or more outputs comprising an indication of the one or more cut specifications and a location of the plurality of locations associated with each portion of the piece of material.

17. The system of claim 13, wherein the UI comprises at least one of the one or more cut specifications, one or more dimensions of the piece of material, the respective portions of the piece of material, or respective locations associated with each respective portion of the piece of material.

18. The system of claim 13, wherein the set of one or more processing devices is to perform operations further comprising:
maintaining a progress indicator for a subset of the one or more pieces of materials of a same type and dimension that are associated with a same cut specification.

19. The system of claim 13, wherein the set of one or more processing devices is to perform operations further comprising:
generating a list of the one or more cut specifications ordered such that the piece of material is maximally utilized.

20. A non-transitory computer readable storage medium storing instructions which, when executed, cause a processing device to perform operations comprising:
obtaining a blueprint for a construction project, the blueprint comprising a plurality of locations, a plurality of material dimensions, and a plurality of material types;
for each of the plurality of material types, obtaining one or more pieces of materials for the construction project, each piece of material having a standard dimension;
determining one or more cut specifications for a piece of material of the one or more pieces of materials of standard dimensions based on the blueprint, wherein respective portions of the piece of material are associated with a respective location of the plurality of locations;
displaying the one or more cut specifications, each portion of the piece of material, and the respective location associated with each portion; and
enabling a user, using a graphic user interface (UI) of an application that determines and displays the one or more cut specifications and locations associated with each portion of the piece of material, to cut the piece of material such that the piece of material is maximally utilized between the plurality of locations.
